(19) United States
(12) Patent Application Publication
(10) Pub. No.: US 2021/0104411 A1
(43) Pub. Date: Apr. 8, 2021

(54) ETCHING SOLUTION, AND METHOD OF PRODUCING SEMICONDUCTOR DEVICE

(71) Applicant: TOKYO OHKA KOGYO CO., LTD., Kawasaki-shi (JP)

(72) Inventors: Ming-Yen Chung, Hsinchu City (TW); Po Ting Chou, Hsinchu City (TW)

(21) Appl. No.: 17/060,453

(22) Filed: Oct. 1, 2020

(30) Foreign Application Priority Data
Oct. 4, 2019 (JP) 2019-183804
Sep. 16, 2020 (JP) 2020-155651

(51) Int. Cl. H01L 21/311; C09K 13/06; H01L 21/306

(52) U.S. Cl. CPC H01L 21/31105; H01L 21/30617; C09K 13/06

(57) ABSTRACT

A SiGe compound etching solution for selectively etching a compound represented by general formula Si₁₋ₓGeₓ (provided that x is 0 or more and less than 1) relative to Si, Ge and an oxide thereof, the SiGe compound etching solution including a fluoride and an oxidizing agent, wherein the fluoride includes hexafluorosilicic acid, and an etching rate A as measured under the following conditions is 10 Å/min or more: a blanket substrate having a layer of Si_{0.75}Ge_{0.25} on the surface thereof is immersed in an etching solution at 25° C., and the etching rate is measured.

### TECHNICAL FIELD

The present invention relates to an etching solution, and a method of producing a semiconductor device.

Priority is claimed on Japanese Patent Application No. 2019-183804, filed Oct. 4, 2019, and Japanese Patent Application No. 2020-155651, filed Sep. 16, 2020, the contents of which are incorporated herein by reference.

### DESCRIPTION OF RELATED ART

Conventionally, scaling of the configuration in an integrated circuit has made it possible to increase the density of functional units on a semiconductor chip. For example, shrinking transistor size allows for the incorporation of an increased number of memory devices on a chip, leading to the fabrication of products with increased capacity.

In the manufacture of field effect transistors (FETs) for integrated circuit devices, Ge is used as a semiconductor crystal material other than silicon. Ge offers a number of potentially advantageous features relative to silicon, such as high charge carrier (hole) mobility, band gap offset, a different lattice constant, and the ability to alloy with silicon to form semiconducting binary alloys of SiGe.

Various etching solutions with high selectivity for Ge materials (particularly, compounds represented by the general formula Si₁₋ₓGeₓ, provided that x is more than 0 and less than 1; hereinafter, may be simply referred to as “SiGe compound”) have been proposed.

For example, Patent Literature 1 describes an etching composition including at least one diol compound, at least one fluoride species and at least one oxidizing species.

### DOCUMENTS OF RELATED ART

### Patent Literature

[Patent Literature 1] Japanese Unexamined Patent Application Publication (Translation of PCT Application) No. 2018-519674

### SUMMARY OF THE INVENTION

However, when a conventional etching solution as described in Patent Document 1 is used, not only the SiGe compound but also Si, SiO₂ and the like are etched. Therefore, it was difficult to selectively etch the SiGe compound relative to Si, SiO₂, and the like.

The present invention takes the above circumstances into consideration, with an object of providing an etching solution capable of selectively etching a compound represented by general formula Si₁₋ₓGeₓ relative to Si, Ge, and oxides thereof, and a method of producing a semiconductor element using the etching solution.

For solving the above-mentioned problems, the present invention employs the following aspects.

A first aspect of the present invention is a SiGe compound etching solution for selectively etching a compound represented by general formula Si₁₋ₓGeₓ (provided that x is 0 or more and less than 1) relative to Si, Ge and an oxide thereof, the SiGe compound etching solution including a fluoride and an oxidizing agent, wherein the fluoride includes hexafluorosilicic acid, and an etching rate A as measured under the following conditions is 10 Å/min or more:

### Measurement Conditions of Etching Rate A

A blanket substrate having a layer of Si_{0.75}Ge_{0.25} on the surface thereof is immersed in an etching solution at 25° C., and the etching rate is measured.

A second aspect of the present invention is a method of producing a semiconductor device, the method including subjecting an object to be treated containing a compound represented by general formula Si₁₋ₓGeₓ to an etching treatment using the etching solution according to the first aspect.

According to the etching solution of the present invention, a compound represented by general formula Si₁₋ₓGeₓ may be selectively etched relative to Si, Ge, and oxides thereof.

Further, by the method of producing a semiconductor element according to the present invention, a semiconductor element in which a compound represented by general formula Si₁₋ₓGeₓ has been selectively etched relative to Si, Ge, and oxides thereof may be produced.

### DETAILED DESCRIPTION OF THE INVENTION

### Etching Solution

The etching solution according to the first aspect includes a fluoride and an oxidizing agent, and the fluoride includes hexafluorosilicic acid. The etching solution according to the present embodiment is used for selectively etching a compound represented by general formula Si₁₋ₓGeₓ (provided that x is more than 0 and less than 1) (hereafter, sometimes referred to simply as “SiGe compound”) relative to Si, Ge and an oxide thereof.

The etching solution according to the present embodiment exhibits an etching rate A as measured under the following conditions of 10 Å/min or more, preferably 15 Å/min or more, more preferably 20 Å/min or more, still more preferably 50 Å/min or more, and still more preferably 80 Å/min or more.

### Measurement Conditions of Etching Rate A

A blanket substrate having a layer of Si_{0.75}Ge_{0.25} on the surface thereof is immersed in an etching solution at 25° C., and the etching rate is measured.

By virtue of the etching rate A being 10 Å/min or more, the etching solution of the present embodiment has good selectivity for the SiGe compound. Further, when the etching rate A of the etching solution of the present embodiment is at least the lower limit of the above-mentioned preferable range, the selectivity for the SiGe compound is further enhanced.

When the etching rate measured under the following conditions is defined as an etching rate B, the etching solution of the present embodiment preferably has a ratio A/B of 10 or more, and more preferably a ratio A/B of 15 or more, still more preferably a ratio A/B of 20 or more, still more preferably a ratio A/B of 30 or more, still more preferably a ratio A/B of 70 or more, and still more preferably a ratio A/B of 90 or more.

### Measurement Conditions of Etching Rate B

A blanket substrate having a layer of SiO₂ on the surface thereof is immersed in an etching solution at 25° C., and the etching rate is measured.

When the ratio A/B of the etching solution according to the present embodiment is at least as large as the lower limit of the above-mentioned range, the etching selectivity of the SiGe compound relative to SiO₂ may be further enhanced.

### Fluoride

The etching solution according to the present embodiment contains hexafluorosilicic acid as a fluoride.

Fluorides other than hexafluorosilicic acid are not particularly limited, and examples thereof include hexafluorotitanic acid, hexafluorosilicic acid, hexafluorozirconic acid, tetrafluoroboric acid, tetraalkylammonium tetrafluoroborate (NR₁R₂R₃R₄BF₄) such as tetrabutylammonium trifluoromethanesulfonate or tetrabutylammonium tetrafluoroborate, tetraalkylammonium hexafluorophosphate (NR₁R₂R₃R₄PF₆), tetraalkylammonium fluoride (NR₁R₂R₃R₄F) (or an anhydride or hydrate thereof) such as tetramethylammonium fluoride, ammonium bifluoride, and ammonium fluoride (in the formulae, R₁, R₂, R₃ and R₄ may be the same or different, and represents hydrogen, a linear or branched C₁-C₆ alkyl group (e.g., methyl, ethyl, propyl, butyl, pentyl, hexyl), a C₁-C₆ alkoxy group (e.g., hydroxyethyl, hydroxypropyl), or a substituted or unsubstituted aryl group (e.g., benzyl)).

The etching solution according to the present embodiment preferably contains only hexafluorosilicic acid as the fluoride.

In the etching solution of the present embodiment, as the fluoride, one kind of compound may be used, or two or more kinds of compounds may be used in combination.

The amount of the fluoride in the etching solution of the present embodiment is not particularly limited. The amount of fluoride with respect to the total mass of the etching solution is, for example, 0.02 to 5% by mass, preferably 0.025 to 3.00% by mass, more preferably 0.03 to 2.50% by mass, and still more preferably 0.04 to 2.00% by mass. When the amount of fluoride is within the above-mentioned range, the etching rate with respect to the SiGe compound may be more reliably improved.

The fluoride ion concentration in the etching solution of the present embodiment is not particularly limited. The fluoride ion concentration in the etching solution is, for example, 0.005 to 2.50 mol/L, preferably 0.007 to 1.50 mol/L, more preferably 0.008 to 1.25 mol/L, and still more preferably 0.010 to 1.00 mol/L. When the fluorine ion concentration is within the above-mentioned range, the etching rate with respect to the SiGe compound may be more reliably improved.

### Oxidizing Agent

Examples of the oxidizing agent include hydrogen peroxide, FeCl₃, FeF₃, Fe(NO₃)₃, Sr(NO₃)₂, CoF₃, MnF₃, Oxone (2KHSO₅.KHSO₄.K₂SO₄), iodic acid, vanadium oxide (V), vanadium oxide (IV, V), ammonium vanadate, ammonium peroxomonosulfate, ammonium chlorite, ammonium chlorate, ammonium iodate, ammonium nitrate, ammonium perborate, ammonium perchlorate, ammonium periodate, ammonium persulfate, ammonium hypochlorite, ammonium hypobromite, ammonium tungstate, sodium persulfate, sodium hypochlorite, sodium perborate, sodium hypobromite, potassium iodate, potassium manganate, potassium persulfate, nitric acid, potassium persulfate, potassium hypochlorite, tetramethylammonium chlorite, tetramethylammonium chlorate, tetramethylammonium iodate, tetramethylammonium perborate, tetramethylammonium perchlorate, tetramethylammonium periodate, tetramethylammonium persulfate, tetrabutylammonium peroxomonosulfate, peroxomonosulfuric acid, ferric nitrate, urea peroxide, peracetic acid, orthoperiodic acid (H₅IO₆), metaperiodic acid (HIO₄), methyl-1,4-benzoquinone (MBQ), 1,4-benzoquinone (BQ), 1,2-benzoquinone, 2,6-dichloro-1,4-benzoquinone (DCBQ), tolquinone, 2,6-dimethyl-1,4-benzoquinone (DMBQ), chloranil, alloxan, N-methylmorpholine N-oxide, and trimethylamine N-oxide.

Among these examples, as the oxidizing agent, nitric acid or orthoperiodic acid is preferable, and nitric acid is more preferable.

In the etching solution of the present embodiment, as the oxidizing agent, one kind of compound may be used, or two or more kinds of compounds may be used in combination.

The amount of the oxidizing agent with respect to the total mass of the etching solution is, for example, 5 to 50% by mass, preferably 5.5 to 45% by mass, more preferably 6 to 40% by mass, and still more preferably 7 to 35% by mass.

When the amount of the oxidizing agent is within the above-mentioned range, the SiGe compound may be more reliably oxidized, and the etching rate of the etching solution with respect to the SiGe compound may be further enhanced.

### Other Components

The etching solution of the present embodiment may contain, in addition to the above components, other components as long as the effects of the present invention are not impaired. Examples of other components include a solvent, a pH adjuster, a passivation agent, and a surfactant.

### Solvent

The etching solution of the present embodiment is preferably prepared by mixing hydrofluoric acid, an oxidizing agent and other optional components with a solvent.

The solvent is not particularly limited, and examples thereof include water and a polar organic solvent, and phosphoric acid and/or a derivative thereof.

### Water

In the case where the etching solution of the present embodiment contains water as a solvent, the water may contain trace components that are inevitably mixed. The water used in the etching solution of the present embodiment is preferably water that has been subjected to purification treatment, such as distilled water, ion-exchanged water, and ultrapure water, more preferably ultrapure water that is generally used in semiconductor manufacturing.

In the case where the etching solution of the present embodiment contains water, the amount of water with respect to the total mass of the etching solution is, for example, 3 to 50% by mass, preferably 3.5 to 45% by mass, more preferably 4 to 40% by mass, and still more preferably 4.5 to 40% by mass.

### Polar Organic Solvent

The etching solution of the present embodiment may contain a polar organic solvent, as long as the effects of the present invention are not impaired. Examples of the polar organic solvent include an organic carboxylic acid solvent (e.g., acetic acid and formic acid), an alcohol solvent (e.g., methanol, ethanol, ethylene glycol, propylene glycol, glycerin, 1,3-propanediol, 1,3-butanediol, 1,4-butanediol, diethylene glycol, dipropylene glycol, furfuryl alcohol, and 2-methyl-2,4-pentanediol), dimethyl sulfoxide, and ethers (such as ethylene glycol dimethyl ether, diethylene glycol dimethyl ether, triethylene glycol dimethyl ether, tetraethylene glycol dimethyl ether, propylene glycol dimethyl ether).

Among these examples, as the polar organic solvent, an organic carboxylic acid is preferable, and acetic acid is more preferable.

In the etching solution of the present embodiment, as the polar organic solvent, one kind of compound may be used, or two or more kinds of compounds may be used in combination.

In the case where the etching solution of the present embodiment contains a polar organic solvent, the amount of the polar organic solvent with respect to the total mass of the etching solution is, for example, 20 to 90% by mass, preferably 25 to 85% by mass, more preferably 30 to 80% by mass, and still more preferably 35 to 75% by mass.

### Phosphoric Acid and/or Derivative Thereof

The etching solution of the present embodiment may contain phosphoric acid and/or a derivative thereof, as long as the effects of the present invention are not impaired. Examples of phosphoric acid and/or a derivative thereof include a compound represented by general formula (1) shown below.

[Chemical Formula 1]

O═P(OR)₃ (1)

In the formula, each R independently represents a hydrogen atom or an alkyl group having 1 to 20 carbon atoms.

In formula (1), examples of the alkyl group having 1 to 20 carbon atoms represented by R include a methyl group, an ethyl group, a propyl group, a butyl group, a pentyl group, a hexyl group, a heptyl group, an octyl group, a nonyl group, a decyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, and isomers of the above alkyl groups.

Among these examples, as R, a hydrogen atom or an alkyl group having 1 to 10 carbon atoms is preferable, and a hydrogen atom is more preferable.

In the etching solution of the present embodiment, as phosphoric acid and/or a derivative thereof, one kind of compound may be used, or two or more kinds of compounds may be used in combination.

In the case where the etching solution of the present embodiment contains phosphoric acid and/or a derivative thereof, the amount of phosphoric acid and/or a derivative thereof with respect to the total mass of the etching solution is, for example, 1 to 50% by mass, preferably 2 to 45% by mass, more preferably 3 to 40% by mass, and still more preferably 5 to 35% by mass.

In the etching solution of the present embodiment, as solvent, one kind of compound may be used, or two or more kinds of compounds may be used in combination.

In the etching solution of the present embodiment, as the polar organic solvent, one kind of compound may be used, or two or more kinds of compounds may be used in combination.

In the case where the etching solution of the present embodiment contains a combination of water and a polar organic solvent as the solvent, the mass ratio of water to the polar organic solvent is preferably 1/15 to 1/1, more preferably 1/12 to 9/10, and still more preferably 1/10 to 8/10.

In the case where the etching solution of the present embodiment contains a combination of water and phosphoric acid and/or a derivative thereof, the mass ratio of water to phosphoric acid and/or a derivative thereof is preferably 1/1 to 10/1, more preferably 1.1/1 to 9/1, and still more preferably 1.2/1 to 8/1.

In the case where the etching solution of the present embodiment contains a solvent, the amount of the solvent with respect to the total mass of the etching solution is, for example, 23 to 95% by mass, preferably 23.5 to 94.5% by mass, more preferably 24 to 94% by mass, and still more preferably 24.5 to 93.5% by mass.

### pH Adjuster

For further improving the etching rate with respect to the SiGe compound, the etching solution of the present embodiment may contain a pH adjuster.

As the pH adjuster, at least one member selected from the group consisting of acids and salts thereof is preferable. Specifically examples thereof include methanesulfonic acid, trifluoromethanesulfonic acid, oxalic acid dihydrate, citric acid, tartaric acid, picolinic acid, succinic acid, acetic acid, lactic acid, sulfosuccinic acid, benzoic acid, propionic acid, formic acid, pyruvic acid, maleic acid, malonic acid, fumaric acid, malic acid, ascorbic acid, mandelic acid, heptanoic acid, butyric acid, valeric acid, glutaric acid, phthalic acid, hypophosphorous acid, salicylic acid, 5-sulfosalicylic acid, hydrochloric acid, ethanesulfonic acid, butanesulfonic acid, p-toluenesulfonic acid, dichloroacetic acid, difluoroacetic acid, monochloroacetic acid, monofluoroacetic acid, trichloroacetic acid, trifluoroacetic acid, hydrobromic acid (62% by weight), sulfuric acid, ammonium acetate, sodium acetate, potassium acetate, tetramethylammonium acetate and other tetraalkylammonium acetates, phosphonium acetate, ammonium butyrate, ammonium trifluoroacetate, ammonium carbonate, ammonium chloride, ammonium sulfate, phosphoric acid, diammonium hydrogen phosphate, ammonium dihydrogen phosphate, bis(tetramethylammonium) hydrogen phosphate, disodium hydrogen phosphate, phosphorus sodium dihydrogen phosphate, dipotassium hydrogen phosphate, potassium dihydrogen phosphate, ditetraalkyl ammonium hydrogen phosphate, ditetraalkyl ammonium dihydrogen phosphate, diphosphonium hydrogen phosphate, phosphonium dihydrogen phosphate, ammonium phosphonate, tetraalkylammonium phosphonate, sodium phosphonate, potassium phosphonate, phosphonium phosphonate, etidronic acid, and salts thereof.

Among the above examples, as the acid for the pH adjuster, methanesulfonic acid or oxalic acid is preferable.

The etching solution of the present embodiment may contain, as a pH adjuster, a basic compound. As such basic compounds, organic alkaline compounds and inorganic alkaline compounds can be used. Preferable examples of organic alkaline compounds include quaternary ammonium salts including organic quaternary ammonium hydroxides, and alkylamines and derivatives thereof, such as trimethylamine and triethylamine

Examples of the inorganic alkaline compound include inorganic compounds containing alkali metals or alkaline earth metals and salts thereof. Examples thereof include lithium hydroxide, sodium hydroxide, potassium hydroxide, rubidium hydroxide and cesium hydroxide.

In the etching solution of the present embodiment, as the pH adjuster, one kind of compound may be used, or two or more kinds of compounds may be used in combination.

In the case where the etching solution of the present embodiment contains a pH adjuster, the amount of the pH adjuster with respect to the total mass of the etching solution is, for example, 0.01 to 10% by mass, preferably 0.02 to 4.5% by mass, more preferably 0.03 to 4% by mass, and still more preferably 0.05 to 3% by mass. When the amount of the pH adjuster is within the above-mentioned range, the etching rate with respect to the SiGe compound may be more reliably improved.

### Passivation Agent

The etching solution of the present embodiment may contain a passivation agent for germanium.

Examples of the passivation agent include ascorbic acid, L (+)-ascorbic acid, isoascorbic acid, ascorbic acid derivatives, boric acid, ammonium diborate, borates (e.g., ammonium pentaborate, sodium tetraborate and ammonium biborate), alanine, arginine, asparagine, aspartic acid, cysteine, glutamic acid, glutamine, histidine, isoleucine, leucine, lysine, methionine, phenylalanine, proline, serine, threonine, tryptophan, tyrosine, valine, sodium bromide, potassium bromide, Rubidium bromide, magnesium bromide, calcium bromide, and ammonium bromide represented by the formula NR¹R²R³R⁴Br (in the formula, R¹, R², R³ and R⁴ may be the same as or different from each other, and selected from the group consisting of hydrogen, and branched or straight-chain C₁-C₆alkyl (such as methyl, ethyl, propyl, butyl, pentyl, and hexyl).

In the etching solution of the present embodiment, as the passivation agent, one kind of compound may be used, or two or more kinds of compounds may be used in combination.

When the etching solution of the present embodiment contains a passivation agent, the amount of the passivation agent with respect to the total mass of the etching solution is preferably 0.01 to 5% by mass, more preferably 0.1 to 1% by mass.

### Surfactant

The etching solution of the present embodiment may contain a surfactant for the purpose of adjusting the wettability of the etching solution with respect to the target object (object to be treated). As the surfactant, a nonionic surfactant, an anionic surfactant, a cationic surfactant, or an amphoteric surfactant may be used, and these may be used in combination.

Examples of nonionic surfactants include polyalkylene oxide alkylphenyl ether surfactants, polyalkylene oxide alkyl ether surfactants, block polymer surfactants composed of polyethylene oxide and polypropylene oxide, and polyoxyalkylene distyrenated phenyl ether surfactants, polyalkylene tribenzylphenyl ether surfactants, and acetylene polyalkylene oxide surfactants.

Examples of the anionic surfactant include alkyl sulfonic acid, alkyl benzene sulfonic acid, alkyl naphthalene sulfonic acid, alkyl diphenyl ether sulfonic acid, fatty acid amide sulfonic acid, polyoxyethylene alkyl ether carboxylic acid, polyoxyethylene alkyl ether acetic acid, polyoxyethylene alkyl ether propionic acid, alkyl phosphonic acid, and fatty acid salt. Examples of the “salt” include ammonium salt, sodium salt, potassium salt, tetramethylammonium salt and the like.

Examples of the cationic surfactant include a quaternary ammonium salt surfactant, and an alkyl pyridium surfactant.

Examples of amphoteric surfactants include betaine surfactants, amino acid surfactants, imidazoline surfactants, and amine oxide surfactants.

The above surfactants are generally commercially available. As the surfactant, one kind of compound may be used alone, or two or more kinds of compounds may be used in combination.

### Object to be Treated

The etching solution of the present embodiment is used for SiGe compound etching, and an object to be treated including SiGe compound is the target of the etching processing. The object to be treated is not particularly limited as long as the object includes SiGe compound and examples thereof include a substrate having a SiGe compound-containing layer (SiGe compound-containing film) or the like. The substrate is not particularly limited and examples thereof include various substrates such as a semiconductor wafer, a glass substrate for a photomask, a glass substrate for a liquid crystal display, a glass substrate for a plasma display, a substrate for a field emission display (FED), a substrate for an optical disk, a substrate for a magnetic disk, and substrate for a magneto-optical disk. As the substrate, a substrate used for semiconductor device production is preferable. In addition to the SiGe compound-containing layer and the base material of the substrate, the substrate may have various layers and structures as appropriate, such as, for example, metal wiring, a gate structure, a source structure, a drain structure, an insulating layer, a ferromagnetic layer, a nonmagnetic layer, and the like. In addition, the uppermost layer on the device surface of the substrate does not need to be the SiGe compound-containing layer and, for example, the intermediate layer of the multilayer structure may be the SiGe compound-containing layer.

The size, thickness, shape, layer structure, and the like of the substrate are not particularly limited and may be appropriately selected depending on the purpose.

The SiGe compound-containing layer is preferably a layer containing a SiGe compound, and more preferably a SiGe compound film. The thickness of the SiGe compound-containing layer on the substrate is not particularly limited, and may be appropriately selected depending on the purpose. Examples of the thickness of the SiGe compound-containing layer include a range of 1 to 500 nm and 1 to 300 nm.

Besides a SiGe compound, the object to be treated may contain at least one member selected from the group consisting of Si, Ge and oxides thereof, preferably SiO₂.

The etching solution of the present embodiment may be used for performing fine processing of the SiGe compound-containing layer in the substrate, may be used for removing SiGe compound-containing deposits attached to the substrate, and may be used to remove impurities such as particles from the object to be treated having the SiGe compound-containing layer on the surface.

Since the etching solution of the present embodiment described above includes hexafluorosilicic acid as a fluoride, the etching solution is capable of selectively etching a compound represented by general formula Si₁₋ₓGeₓ (SiGe compound) relative to Si, Ge, and oxides thereof. The reason therefor has not been elucidated yet, but is presumed as follows. When the etching solution of the present embodiment is allowed to come into contact with an objected to be treated containing a SiGe compound, the SiGe compound is oxidized by the oxidizing agent. The oxide of the SiGe compound is etched by the fluoride ion (F⁻) in hexafluorosilicic acid. On the other hand, silicon (Si) within hexafluorosilicic acid exhibits the function of protecting SiO₂ and the like from being etched by fluoride ion (F⁻). Therefore, it is presumed that the etching solution of the present embodiment exhibits increased selectivity for a SiGe compound relative to Si, Ge and oxides thereof, as compared to a conventional etching solution using a fluoride such as hydrofluoric acid (HF) or ammonium fluoride (NH₄F).

### Method of Producing Semiconductor Device

The method of producing a semiconductor device according to the second aspect of the present invention includes subjecting an object to be treated containing a SiGe compound to an etching treatment using the etching solution according to the first aspect.

The object to be treated containing a SiGe compound is the same as defined for the “object to be treated” described above for the etching solution, and preferable examples thereof include a substrate having a SiGe compound-containing layer. The method for forming the ruthenium-containing layer on the substrate is not particularly limited and it is possible to use known methods. Examples of such methods include a sputtering method, a chemical vapor deposition (CVD) method, a molecular beam epitaxy (MBE) method, an atomic layer deposition (ALD) method, and the like. The raw material of the ruthenium-containing layer used when forming the ruthenium-containing layer on the substrate is not particularly limited, and appropriate selection thereof is possible according to the film forming method.

Besides a SiGe compound, the object to be treated may contain at least one member selected from the group consisting of Si, Ge and oxides thereof, preferably SiO₂.

### Step of Subjecting Object to Etching Treatment

This step is a step of carrying out an etching process on the object to be treated containing a SiGe compound, using the etching solution according to the first aspect, and includes an operation of bringing the etching solution into contact with the object to be treated. The etching treatment method is not particularly limited and it is possible to use a known etching method. Examples of such methods include a spray method, an immersion method, a liquid filling method, or the like, without being limited thereto.

In the spray method, for example, the object to be treated is transported or rotated in a predetermined direction, the etching solution according to the first aspect is sprayed into the space such that the etching solution is brought into contact with the object to be treated. If desired, the etching solution may be sprayed while rotating the substrate using a spin coater.

In the immersion method, the object to be treated is immersed in the etching solution according to the first aspect and the etching solution is brought into contact with the object to be treated.

In the liquid filling method, the etching solution according to the first aspect is placed on the object to be treated and the object to be treated and the etching solution are brought into contact with each other.

It is possible to appropriately select these etching process methods depending on the structure, materials, and the like of the object to be treated. In a case of the spray method or the liquid filling method, it is sufficient if the supply amount of the etching solution to the object to be treated is an amount by which the surface to be treated in the object to be treated is sufficiently wetted by the etching solution.

The purpose of the etching treatment is not particularly limited and may be fine processing for a surface to be treated of the object to be treated containing SiGe compound (for example, a SiGe compound-containing layer on a substrate), may be removal of a SiGe compound-containing deposit attached to the object to be treated (for example, a substrate having a SiGe compound-containing layer), or may be cleaning of a surface to be treated of the object to be treated containing SiGe compound (for example, a SiGe compound-containing layer on the substrate).

In a case where the purpose of the etching treatment is fine processing of the surface to be treated of the object to be treated including SiGe compound, generally, the portion not to be etched is covered with an etching mask and the object to be treated and the etching solution are brought into contact with each other.

In a case where the purpose of the etching treatment is the removal of SiGe compound-containing deposits attached to the object to be treated, the SiGe compound-containing deposits are dissolved by bringing the etching solution according to the first aspect into contact with the object to be treated and it is possible to remove the SiGe compound deposits from the object to be treated.

In a case where the purpose of the etching treatment is to clean the surface to be treated of the object to be treated including ruthenium, the surface to be treated is rapidly dissolved by bringing the etching solution according to the first aspect into contact with the object to be treated and impurities such as particles attached to the surface of the object to be treated are removed from the surface of the object to be treated in a short time.

The temperature at which the etching treatment is performed is not particularly limited as long as the SiGe compound is dissolved with the etching solution. Examples of the temperature for the etching process include 15° C. to 60° C. In a case of any of the spray method, the immersion method, and the liquid filling method, the etching rate is increased by increasing the temperature of the etching solution, but it is possible to appropriately select the processing temperature in consideration of suppressing composition changes in the etching solution to be small, or workability, safety, cost, and the like.

The time for performing the etching treatment may be appropriately selected according to the purpose of the etching treatment, the amount of SiGe compound to be removed by the etching (for example, the thickness of the SiGe compound-containing layer, the amount of SiGe compound deposits, and the like) and the etching treatment conditions.

### Other Steps

The method of producing a semiconductor device according to the present embodiment may include other steps in addition to the etching treatment step described above. The other steps are not particularly limited and examples thereof include known steps performed when manufacturing a semiconductor device. Examples of the steps include a step for forming each structure such as a metal wiring, a gate structure, a source structure, a drain structure, an insulating layer, a ferromagnetic layer, and a nonmagnetic layer (layer formation, etching other than the etching process described above, chemical mechanical polishing, modification, and the like), a resist film formation step, an exposure step, a development step, a heating process step, a cleaning step, an inspection step, and the like, without being limited thereto. It is possible to appropriately perform these other steps before or after the etching process step if desired.

In the method of producing a semiconductor element according to the present embodiment described above, an object to be treated is subjected to an etching treatment using the etching solution of the first aspect containing hexafluorosilicic acid as the fluoride. The etching solution is capable of selectively etching a compound represented by general formula Si₁₋ₓGeₓ (SiGe compound) relative to Si, Ge, and oxides thereof. Therefore, by the method of producing a semiconductor element according to the present embodiment, a semiconductor element having a SiGe compound being etched may be obtained without any substantial influence of Si, Ge, and oxides thereof.

### EXAMPLES

As follows is a description of examples of the present invention, although the scope of the present invention is by no way limited by these examples.

### Preparation of Etching Solution (1)

### Examples 1 to 9, Comparative Examples 1 and 2

The components shown in Table 1 were mixed together to obtain each etching solution.

TABLE 1

| | | | | Oxidizing | | |
|---|---|---|---|---|---|---|
| | Fluoride | | | agent | Solvent | |
| | H₂SiF₆ | HF | NH₄F | HNO₃ | AcOH | Water |
| Example 1 | 0.1 | | | 30 | 57 | 12.9 |
| Example 2 | 0.5 | | | 10 | 57 | 32.5 |
| Example 3 | 0.5 | | | 20 | 54 | 25.5 |
| Example 4 | 0.5 | | | 25 | 55 | 19.5 |
| Example 5 | 0.5 | | | 30 | 55 | 14.5 |
| Example 6 | 0.5 | | | 30 | 40 | 29.5 |
| Example 7 | 0.5 | | | 30 | 45 | 24.5 |
| Example 8 | 0.6 | | | 30 | 57 | 12.4 |
| Example 9 | 0.9 | | | 30 | 54 | 15.1 |
| Comparative | | 0.2 | | 30 | 57 | 12.8 |
| Example | | | | | | |
| Comparative | | | 0.37 | 30 | 57 | 12.63 |
| Example | | | | | | |

In Table 1, the reference characters indicate the following. The values in brackets [ ] indicate the amount (in terms of parts by mass) of the component added.

H₂SiF₆: hexafluorosilicic acid

HF: hydrofluoric acid

NH₄F: ammonium fluoride

HNO₃: nitric acid

AcOH: acetic acid

### Etching Treatment of Object (1)

A blanket substrate having a layer of Si_{0.75}Ge_{0.25} on the surface thereof was immersed in an etching solution at 25° C., and the etching rate was measured. The results are shown in Table 2.

### Etching Treatment of Object (2)

A SOI substrate was immersed in an etching solution at 25° C., and the etching rate was measured. The results are shown in Table 2.

### Etching Treatment of Object (3)

A blanket substrate having a layer of SiO₂ on the surface thereof was immersed in an etching solution at 25° C., and the etching rate was measured. The results are shown in Table 2.

TABLE 2

| | Etching rate (A/min) | | | Etching selectivity ratio | |
|---|---|---|---|---|---|
| | Si_{0.75}Ge_{0.25} | Si | SiO₂ | Si_{0.75}Ge_{0.25}/Si | Si_{0.75}Ge_{0.25}/SiO₂ |
| Example 1 | 28 | 0.5 | 0.5 | 55 | 51 |
| Example 2 | 12 | 0.1 | 0.5 | 101 | 24 |
| Example 3 | 66 | 0.2 | 0.8 | 302 | 86 |
| Example 4 | 140 | 0.4 | 1.0 | 323 | 137 |
| Example 5 | 221 | 0.4 | 1.6 | 570 | 136 |
| Example 6 | 204 | 0.1 | 1.6 | 1685 | 132 |
| Example 7 | 302 | 0.2 | 1.4 | 1392 | 209 |
| Example 8 | 152 | 0.7 | 0.4 | 234 | 434 |
| Example 9 | 289 | 0.7 | 1.9 | 397 | 153 |
| Comparative | 22 | 6.0 | 10.1 | 4 | 2 |
| Example | | | | | |
| Comparative | 21 | 1.9 | 9.9 | 12 | 2 |
| Example | | | | | |

From the results shown in Table 2, it was confirmed that the etching solutions of Examples 1 to 9 exhibited a high SiGe etching selectivity ratio as compared to the etching solutions of Comparative Examples 1 and 2.

### Preparation of Etching Solution (2)

### Examples 10 to 13, Comparative Examples 3 and 4

The components shown in Table 3 were mixed together to obtain each etching solution.

TABLE 3

| | | | Oxidizing | | |
|---|---|---|---|---|---|
| | Fluoride | | agent | Solvent | |
| | H₂SiF₆ | HF | HNO₃ | H₃PO₄ | Water |
| Example 10 | 0.19 | | 30 | 25.5 | 44.3 |
| Example 11 | 0.5 | | 30 | 10 | 59.5 |
| Example 12 | 0.5 | | 30 | 15 | 54.5 |
| Example 13 | 0.5 | | 30 | 25.5 | 44.0 |
| Comparative | | 0.1 | 30 | 25.5 | 44.5 |
| Example | | | | | |
| Comparative | | 0.2 | 30 | 25.5 | 44.5 |
| Example | | | | | |

In Table 3, the reference characters indicate the following. The values in brackets [ ] indicate the amount (in terms of parts by mass) of the component added.

H₂SiF₆: hexafluorosilicic acid

HF: hydrofluoric acid

HNO₃: nitric acid

H₃PO₄: phosphoric acid

### Etching Treatment of Object (1)

A blanket substrate having a layer of Si_{0.75}Ge_{0.25} on the surface thereof was immersed in an etching solution at 25° C., and the etching rate was measured. The results are shown in Table 4.

### Etching Treatment of Object (2)

A SOI substrate was immersed in an etching solution at 25° C., and the etching rate was measured. The results are shown in Table 4.

### Etching Treatment of Object (3)

A blanket substrate having a layer of SiO₂ on the surface thereof was immersed in an etching solution at 25° C., and the etching rate was measured. The results are shown in Table 4.

TABLE 4

| | Etching rate (A/min) | | | Etching selectivity ratio | |
|---|---|---|---|---|---|
| | Si_{0.75}Ge_{0.25} | Si | SiO₂ | Si_{0.75}Ge_{0.25}/Si | Si_{0.75}Ge_{0.25}/SiO₂ |
| Example 10 | 68 | 1.9 | 2.4 | 36 | 28 |
| Example 11 | 41 | 0.5 | 3.6 | 90 | 11 |
| Example 12 | 107 | 3.0 | 5.1 | 36 | 21 |
| Example 13 | 205 | 8.0 | 7.8 | 26 | 26 |
| Comparative | 343 | 15.9 | 80.5 | 22 | 4 |
| Example | | | | | |
| Comparative | 1168 | 55.4 | 213 | 21 | 5 |
| Example | | | | | |

From the results shown in Table 4, it was confirmed that the etching solutions of Examples 10 to 13 exhibited a high SiGe etching selectivity ratio as compared to the etching solutions of Comparative Examples 3 and 4.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A SiGe compound etching solution for selectively etching a compound represented by general formula Si₁₋ₓGeₓ (provided that x is 0 or more and less than 1) relative to Si, Ge and an oxide thereof,
the SiGe compound etching solution comprising a fluoride and an oxidizing agent,
wherein the fluoride includes hexafluorosilicic acid, and
an etching rate A as measured under the following conditions is 10 Å/min or more:
(measurement conditions of etching rate A)
a blanket substrate having a layer of Si_{0.75}Ge_{0.25} on the surface thereof is immersed in an etching solution at 25° C., and the etching rate is measured.

2. The etching solution according to claim 1, further comprising a polar organic solvent.

3. The etching solution according to claim 1, further comprising phosphoric acid and/or a derivative thereof.

4. The etching solution according to claim 1, wherein the oxidizing agent is nitric acid.

5. The etching solution according to claim 1, wherein, when an etching rate measured under the following conditions is defined as an etching rate B, the etching solution has a ratio A/B of 10 or more:
(measurement conditions of etching rate B)
a blanket substrate having a layer of SiO₂ on the surface thereof is immersed in an etching solution at 25° C., and the etching rate is measured.

6. A method of producing a semiconductor device, the method comprising:
subjecting an object to be treated containing a compound represented by general formula Si₁₋ₓGeₓ to an etching treatment using the etching solution according to claim 1.

7. The method according to claim 6, wherein the object to be treated further comprises SiO₂.
